(19) United States
(12) Patent Application Publication
(10) Pub. No.: US 2026/0165067 A1
(43) Pub. Date: Jun. 11, 2026

(54) APPARATUS AND METHODS FOR FILLING GAP FEATURES OF A SUBSTRATE AND RELATED SEMICONDUCTOR DEVICES

(71) Applicant: ASM IP Holding B.V., Almere (NL)

(72) Inventors: Shibesh Dutta, Almere (NL); Werner Knaepen, Leuven (BE)

(21) Appl. No.: 19/405,653

(22) Filed: Dec. 2, 2025

Related U.S. Application Data
(60) Provisional application No. 63/728,509, filed on Dec. 5, 2024.

(51) Int. Cl. H01L 21/67; H01L 21/3205; H01L 21/768; H10B 41/27; H10B 41/41

(52) U.S. Cl. CPC H10P 72/0421; H10B 41/27; H10B 41/41; H10P 14/412; H10W 20/057

(57) ABSTRACT

The disclosure relates to semiconductor processing, specifically an apparatus and methods for partially fabricating a semiconductor device using a cyclical deposition-etch process. The apparatus includes at least one reactor with a reaction chamber, a metal precursor source for delivering metal precursor vapor, and an etchant source for delivering etchant vapor. A vapor distribution and removal system supplies these vapors to the reaction chamber and removes them afterward. A sequence controller, connected to the distribution and removal system, includes a memory with a program that controls vapor flow from the metal precursor source during one or more deposition cycles.

### CROSS-REFERENCE TO RELATED APPLICATIONS

This application claims priority to U.S. Provisional Patent Application Ser. No. 63/728,509 filed Dec. 5, 2024 titled APPARATUS AND METHODS FOR FILLING GAP FEATURES OF A SUBSTRATE AND RELATED SEMICONDUCTOR DEVICES, the disclosure of which is hereby incorporated by reference in its entirety.

### FIELD OF INVENTION

The present disclosure generally relates to the field of semiconductor processing, and specifically to an apparatus and methods for partially fabricating a semiconductor device by a cyclical deposition-etch process. The present disclosure further relates to the provision of related semiconductor devices, such as memory devices and substructures thereof.

### BACKGROUND OF THE DISCLOSURE

Semiconductor fabrication processes for creating devices such as memory elements, transistors, integrated circuits, and their substructures typically involve multi-step procedures that precisely manipulate materials at atomic and nanometer scales. These steps often include deposition, etching, thermal annealing, lithography, and doping—each of which often demands specialized tools and precise control to achieve the desired device characteristics.

However, the increasing complexity of modern semiconductor devices, coupled with shrinking feature sizes and the introduction of advanced materials, has made it challenging to use a wide range of disparate tools efficiently. The need for tight integration between these processes, along with the demand for improved uniformity, scalability, and yield, has further amplified these challenges.

In view of the above, there remains a need to streamline workflows, enhance compatibility between different fabrication steps, and improve the overall efficiency of semiconductor manufacturing. It is therefore an object of the present disclosure to provide simplified and reliable apparatus and methods for controlled semiconductor processing.

### SUMMARY OF THE DISCLOSURE

It has now been found herein that some or all of the above challenges can be addressed and objectives can be achieved, either individually or in any combination, by using the apparatus and methods as described herein.

The present summary provides an introduction to a selection of concepts in a simplified form. These concepts are described in further detail in the detailed description of exemplary embodiments of the disclosure below. This summary is not intended to identify key features or essential features of the claimed subject matter, nor is it intended to be used to limit the scope of the claimed subject matter.

In general, the technology disclosed herein relates to the field of semiconductor processing, specifically to an apparatus and methods for streamlining deposition and etching processes for precisely shaping and/or defining one or more features of a semiconductor device such as trenches, vias, or isolated components.

In particular, the apparatus as described herein enables the integration of the deposition and etching processes within a single reactor (i.e., the same tool). This configuration offers several key advantages over state of the art reactor, reducing and advantageously eliminating the need for substrate transfer between separate tools, as required by conventional apparatus and methods.

Another advantage of combining metal-containing film deposition and subsequent etching within a single reactor is the improved semiconductor processing rate and reduced dependence on multiple tools. This integration increases throughput, lowers labor costs per substrate, and enhances overall operational efficiency.

Additionally, the described apparatus and methods can optimize existing workflows, offering a cost-effective and easily implementable solution.

In accordance with an aspect of the present disclosure, an apparatus is provided comprising:
at least one reactor comprising at least one reaction chamber constructed and arranged for processing at least one semiconductor substrate; wherein the semiconductor substrate comprises one or more gap features;
a metal precursor source constructed and arranged to provide a vapor of at least one metal precursor comprising at least one metal selected from the group consisting of molybdenum, tungsten, ruthenium, cobalt, nickel, and mixtures thereof;
an etchant source constructed and arranged to provide a vapor of at least one etchant;
a vapor distribution and removal system configured to provide the vapors of the metal precursor source and the etchant source to the at least one reaction chamber within the reactor, and to remove the vapors from the reaction chamber; and
a sequence controller operably connected to the distribution and removal system, comprising a memory provided with a program configured to control the flow from the metal precursor source to the reactor chamber by activating the vapor distribution and removal system during one or more deposition cycles; whereby, as a result of the deposition cycles, a metal-containing film is deposited to at least partially fill the one or more gap features of the semiconductor substrate; and,
wherein the program is further configured to control the flow from the etchant source to the reactor chamber by activating the vapor distribution and removal system during one or more etching cycles; whereby, as a result of the etching cycles, the metal-containing film is subjected to subtractive etching.

In particular embodiments, the apparatus further comprises a reactant source constructed and arranged to provide a vapor of a reactant; wherein the vapor distribution and removal system is further configured to provide the vapor of the reactant source to the reactor; and wherein the program provided on the memory is configured to control the flow of the reactant from the reactant source to the at least one reactor chamber during the one or more deposition cycles.

In particular embodiments, the reactant is selected from the group consisting of oxide reactant, nitrogen reactant, boron reactant, reducing reactant, phosphorous reactant, carbon reactant, sulfur reactant, and combinations thereof.

In particular embodiments, the program provided on the memory is further configured to control the flow from the metal precursor source to the at least one reactor chamber by activating the vapor distribution and removal system during one or more deposition cycles comprised in a cyclic deposition process as part of an atomic layer deposition (ALD) process.

In particular embodiments, the at least one semiconductor substrate further comprises a material selected from the group consisting of silicon, silicon oxide, silicon germanium, carbon doped silicon oxides, silicon nitride, silicon carbide, germanium, gallium arsenide, gallium nitride, glass, sapphire, and combinations thereof.

In particular embodiments, the metal precursor is a metal halide, metal chalcogenide halide, or metal-organic precursor.

In particular embodiments, the etchant comprises one or more halogen-containing-etching compounds.

In particular embodiments, the etchant comprises one or more halogen-containing-etching compounds selected from the group consisting of F₂, Cl₂, Br₂, quaternary ammonium fluorides, quaternary ammonium chlorides, quaternary ammonium bromides, HF, HCl, HBr, tetrafluoroboric acid, tetrachloroboric acid, tetrabromoboric acid, hexafluorosilicic acid, hexachlorosilicic acid, hexabromosilicic acid, tetrabutylammonium tetrafluoroborate, H₂ZrF₆, H₂TiF₆, HPF₆, MoCl₅, WCl₅, ammonium hexafluorosilicate, ammonium hexachlorosilicate, ammonium hexabromosilicate, ammonium hexafluorotitanate, ammonium hexachlorotitanate, ammonium hexabromotitanate, thionyl chloride, and mixtures thereof.

In particular embodiments, the at least one reactor further comprises a heating means configured for providing a temperature within the reactor chamber of between 200° C. and 800° C.

In particular embodiments, the at least one reactor further comprises a pressure regulating mechanism configured for providing a pressure within the reactor chamber between 0.2 Torr and 200 Torr.

In particular embodiments, the apparatus is designed such that one or more of the at least one reactor is a vertical furnace comprising at least one reaction chamber configured to receive and process multiple semiconductor substrates simultaneously.

In particular embodiments, the reactor comprises a reactor housing enclosing the at least one reaction chamber.

In particular embodiments, the reactor comprises a reactor housing enclosing at least a first reaction chamber and a second reaction chamber and a handling chamber configured for transfer of the semiconductor substrate between the first and second reaction chambers; wherein the deposition cycles are performed in the first reaction chamber, and the etching cycles are performed in the second reaction chamber; and wherein the vapor distribution and removal system is further configured to selectively direct the flow of the metal precursor vapor to the first reaction chamber and the flow of the etchant vapor to the second reaction chamber.

In particular embodiments, the reactor comprises a reactor housing enclosing a single reaction chamber; wherein the deposition cycles and etching cycles are performed in the (single) reaction chamber; and wherein the vapor distribution and removal system is further configured to selectively direct and remove the flow of the metal precursor vapor and etchant vapor to the (single) reaction chamber.

Another aspect of the present disclosure provides a method for at least partially fabricating a semiconductor substrate, the method comprising the steps of:
a) providing at least one semiconductor substrate comprising one or more gap features into a reactor comprising at least one reactor chamber;
b) executing one or more deposition cycles within the reactor chamber, each cycle comprising a metal precursor pulse, wherein at least a part of the semiconductor substrate is contacted by at least one metal precursor by introducing the at least one metal precursor into the reactor; wherein the at least one metal precursor comprises at least one metal selected from the group consisting of molybdenum, tungsten, ruthenium, and mixtures thereof; whereby, as a result of the cycles, the metal-containing film is deposited to at least partially fill the one or more gap features of the semiconductor substrate; and;
c) executing one or more etching cycles within the reactor chamber, each cycle comprising an etchant pulse, wherein at least a part of the metal-containing film is contacted by at least one etchant by introducing the at least one etchant into the reactor; whereby, as a result of the cycles, the metal-containing film is subjected to subtractive etching.

In particular embodiments, the at least one deposition cycle further comprises a reactant pulse, wherein at least a part of the semiconductor substrate is contacted by at least one reactant, by introducing the at least one reactant into the reactor; wherein the at least one reactant is selected from the group consisting of oxide reactant, nitrogen reactant, boron reactant, reducing reactant, phosphorous reactant, carbon reactant, sulfur reactant, and combinations thereof.

Another aspect of the present disclosure provides a semiconductor device comprising one or more gap features filled with a metal-containing film prepared with the device according to an aspect of the present disclosure or (preferred) embodiments thereof or by means of the method according to an aspect of the present disclosure or (preferred) embodiments thereof.

In particular embodiments, the reactor comprises a reactor housing enclosing the at least one reaction chamber; wherein the deposition cycles and the etching cycles are performed without removal of the semiconductor substrate from the reactor, specifically the reactor housing.

In particular embodiments, the reactor comprises a reactor housing enclosing at least a first reaction chamber and a second reaction chamber, and a handling chamber configured for transfer of the semiconductor substrate between the first and second reaction chambers; and wherein the deposition cycles are performed in the first reaction chamber and the etching cycles are performed in the second reaction chamber without removal of the semiconductor substrate from the reactor.

In particular embodiments, the reactor comprises a reactor housing enclosing a single reaction chamber; and wherein the deposition cycles and etching cycles are performed within the (single) reaction chamber without removal of the semiconductor substrate from the reactor; preferably without removal of the semiconductor substrate from the (single) reaction chamber.

In particular embodiments, the present semiconductor device is a memory device including at least one of a 3D-NAND device, a DRAM device, a 3D-integrated device, or an integrated logic device, or a partially fabricated memory device structure including at least one of a 3D-NAND device structure, a DRAM device structure, a 3D-integrated device structure, or a partially fabricated integrated logic device structure.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 schematically illustrates an apparatus 100 according to an embodiment of the present disclosure comprising a first reaction chamber 112 and a second reaction chamber 113 as described herein.

FIG. 2 schematically illustrates an apparatus 200 according to another embodiment of the present disclosure comprising a reactor 201 comprising a single reaction chamber 212 as described herein.

FIG. 3 describes a method 300 according to an embodiment of the present disclosure for at least partially fabricating a semiconductor device or a substructure of the semiconductor device, wherein the reactor comprises a single reaction chamber.

FIG. 4 describes a method 400 according to another embodiment of the present disclosure for at least partially fabricating a semiconductor device or a substructure of the semiconductor device, wherein the reactor comprises a single reaction chamber as described herein.

FIG. 5 describes a method 500 according to yet another embodiment of the present disclosure for at least partially fabricating a semiconductor device or a substructure of the semiconductor device wherein the reactor comprises a single reaction chamber, wherein the reactor comprises a first reaction chamber and a second reaction chamber as described herein.

FIG. 6 describes a method 600 according to yet another embodiment of the present disclosure for at least partially fabricating a semiconductor device or a substructure of the semiconductor device wherein the reactor comprises a single reaction chamber, wherein the reactor comprises a first reaction chamber and a second reaction chamber as described herein.

FIG. 7 describes a method 700 according to yet another embodiment of the present disclosure for at least partially fabricating a semiconductor device or a substructure of the semiconductor device wherein the reactor comprises a single reaction chamber, wherein the reactor comprises a first reaction chamber, a second reaction chamber, and a third reaction chamber as described herein.

FIG. 8 schematically illustrates a vertical furnace system 900 according to an embodiment of the present disclosure, comprising at least one reaction chamber as described herein.

FIG. 9 schematically illustrates a cross-sectional view of a semiconductor memory device 800 according to an embodiment of the present disclosure, which is at least partially fabricated using the apparatus and/or method as described herein.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims. Hence, the description below is to be regarded as illustrative in nature, and not as restrictive.

As used herein, the singular forms “a,” “an,” and “the” include both singular and plural referents unless the context clearly dictates otherwise. By way of example, “a step” means one step or more than one step.

The terms “comprising,” “comprises” and “comprised of” as used herein are synonymous with “including,” “includes” or “containing,” “contains,” and are inclusive or open-ended and do not exclude additional, non-recited members, elements, or method steps. The terms also encompass “consisting of” and “consisting essentially of,” which enjoy well-established meanings in patent terminology.

Whereas the terms “one or more” or “at least one”, such as one or more members or at least one member of a group of members, is clear per se, by means of further exemplification, the term encompasses inter alia a reference to any one of said members, or to any two or more of said members, such as, e.g., any ≥3, ≥4, ≥5, ≥6 or ≥7 etc. of said members, and up to all said members. In another example, “one or more” or “at least one” may refer to 1, 2, 3, 4, 5, 6, 7 or more.

The terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

As used herein, the term “and/or” when used in a list of two or more items, means that any one of the listed items can be employed by itself or any combination of two or more of the listed items can be employed. For example, if a list is described as comprising group A, B, and/or C, the list can comprise A alone, B alone, C alone, A and B in combination, A and C in combination, B and C in combination, or A, B, and C in combination.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” or “in a particular embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while certain embodiments described herein include some but not other features included in other embodiments, combinations of features of different embodiments are meant to be within the scope of the disclosure, and form different embodiments, as would be understood by those in the art.

The recitation of numerical ranges by endpoints includes all integer numbers and, where appropriate, fractions subsumed within that range (e.g. 1 to 5 can include 1, 2, 3, 4 when referring to, for example, a number of elements, and can also include 1.5, 2, 2.75 and 3.80, when referring to, for example, measurements). The recitation of endpoints also includes the end point values themselves (e.g., from 1.0 to 5.0 includes both 1.0 and 5.0). Any numerical range recited herein is intended to include all sub-ranges subsumed therein. This applies to numerical ranges irrespective of whether they are introduced by the expression “from . . . to . . . ” or the expression “between . . . and . . . ” or another expression.

As used herein, the terms “about” or “approximately” are used to provide flexibility to a numerical value or range endpoint by providing that a given value may be “a little above” or “a little below” said value or endpoint, depending on the specific context. Hence, the terms “about” or “approximately” as used herein when referring to a measurable value such as a parameter, an amount, a temporal duration, and the like, are meant to encompass variations of and from the specified value or endpoint, such as variations of +/−10% or less, preferably +/−5% or less, more preferably +/−1% or less, and still more preferably +/−0.1% or less of and from the specified value, insofar such variations are appropriate to perform in the disclosed disclosure.

Unless otherwise stated, use of the terms “about” or “approximately” in accordance with a specific number or numerical range should also be understood to provide support for such numerical terms or range without the term “about.” For example, the recitation of “about 30” should be construed as not only providing support for values a little above and a little below 30, but also for the actual numerical value of 30 as well.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

The terms “wt. %,” “vol %,” or “mol %” refers to a weight percentage of a component, a volume percentage of a component, or molar percentage of a component, respectively, based on the total weight, the total volume of material, or total moles, which includes the component.

Reference in this specification may be made to apparatus, devices, structures, systems, or methods that provide “improved” performance (e.g., increased or decreased results, depending on the context). It is to be understood that unless otherwise stated, such “improvement” is a measure of a benefit obtained based on a comparison to apparatus, devices, structures, systems, or methods in the prior art. Furthermore, it is to be understood that the degree of improved performance may vary between disclosed embodiments and that no equality or consistency in the amount, degree, or realization of improved performance is to be assumed as universally applicable.

As used herein, relative terms, such as “left,” “right,” “front,” “back,” “top,” “bottom,” “over,” “under,” etc., are used for descriptive purposes and not necessarily for describing permanent relative positions. It is to be understood that such terms are interchangeable under appropriate circumstances and that the embodiment as described herein are capable of operation in other orientations than those illustrated or described herein unless the context clearly dictates otherwise.

Objects described herein as being “adjacent” to each other reflect a functional relationship between the described objects, that is, the term indicates the described objects must be adjacent in a way to perform a designated function which may be a direct (i.e. physical) or indirect (i.e. close to or near) contact, as appropriate for the context in which the phrase is used.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

As used herein, the term “semiconductor substrate” can refer to any underlying material or materials that can be used to form, or upon which, a device, a circuit, or a film can be formed. The “semiconductor substrate” may be continuous or non-continuous; rigid or flexible; solid or porous; and combinations thereof. A semiconductor substrate can comprise a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

The semiconductor substrate may comprise a material such as crystalline silicon, silicon oxide, strained silicon, silicon germanium, sapphire, doped or undoped polysilicon, doped or undoped silicon, patterned or non-patterned silicon on insulator (SOI), carbon doped silicon oxides, silicon nitride, germanium, gallium arsenide, gallium nitride, glass, or combinations thereof.

The term “semiconductor device structure” as used herein may refer to any portion of a processed, or partially processed, semiconductor structure that is, includes, or defines at least a portion of an active or passive component of a semiconductor device to be formed on or in a semiconductor substrate. For example, semiconductor device structures may include active and passive components of integrated circuits, such as, for example, transistors, memory elements, transducers, capacitors, resistors, conductive lines, conductive vias, and conductive contact pads.

In this disclosure, “gas” can include material that is a gas at normal temperature and pressure (NTP), a vaporized solid and/or a vaporized liquid, and can be constituted by a single gas or a mixture of gases, depending on the context. A gas other than the process gases or purge gases, i.e., a gas introduced without passing through a (gas) distribution and removal system, other gas distribution device, or the like, can be used for, e.g., sealing the reaction space, and can include a seal gas, such as a rare gas.

A “film” or “layer,” as referred to herein, can encompass any continuous or non-continuous structure and material, including any material deposited by the apparatus and methods disclosed herein. For example, a film and/or layer can include two-dimensional materials, three-dimensional materials, nanoparticles, or even partial or full molecular layers or partial or full atomic layers or clusters of atoms and/or molecules, or layers consisting of isolated atoms and/or molecules. A film or layer may comprise material or a layer with pinholes, which may be continuous or non-continuous.

Implementations described herein will be further described below in reference to an apparatus for producing semiconductor devices or substructures thereof. However, it should be clear that other systems that benefit from the present apparatus configured for performing the herein described cyclical deposition-etch process may also be adapted to benefit from the implementations described herein. The apparatus described herein is illustrative and should not be construed or interpreted as limiting the scope of the implementations described herein.

An aspect of the present disclosure provides an apparatus comprising:
at least one reactor comprising at least one reaction chamber constructed and arranged for processing at least one semiconductor substrate; wherein the semiconductor substrate comprises one or more gap features;
a metal precursor source constructed and arranged to provide a vapor of at least one metal precursor comprising at least one metal selected from the group consisting of molybdenum, tungsten, ruthenium, cobalt, nickel, and mixtures thereof;
an etchant source constructed and arranged to provide a vapor of at least one etchant;
a vapor distribution and removal system configured to provide the vapors of the metal precursor source and the etchant source to the at least one reaction chamber within the reactor, and to remove the vapors from the reaction chamber; and
a sequence controller operably connected to the distribution and removal system, comprising a memory provided with a program configured to control the flow from the metal precursor source to the reactor chamber by activating the vapor distribution and removal system during one or more deposition cycles; whereby, as a result of the deposition cycles, a metal-containing film is deposited to at least partially fill the one or more gap features of the semiconductor substrate; and,
wherein the program is further configured to control the flow from the etchant source to the reactor chamber by activating the vapor distribution and removal system during one or more etching cycles; whereby, as a result of the etching cycles, the metal-containing film is subjected to subtractive etching.

In other words, the present disclosure generally relates to a processing apparatus configured for processing semiconductor substrates, and more particularly designed for streamlining processes comprising deposition and etching process steps. For instance, the present apparatus may be particularly suitable for constructing memory devices or partially constructing memory devices.

Advantageously, it has been found that the sequence controller can be configured to precisely control the introduction and removal of reactive gases during a deposition-etch process, which results in well-controlled chemical reactions that provide uniform and reproducible films and other features. Moreover, the sequence controller may adjust the flow rates and introduction timings to further optimize the reaction kinetics.

Another advantage of the present apparatus is that the vapor distribution and removal system is configured to provide both the vapors of the metal precursor source and the etchant source to the reaction chamber(s) of the same reactor.

In particular embodiments, the apparatus may be configured such that the reactor comprises reactor housing enclosing at least a first reaction chamber; at least a second reaction chamber, and at least a handling chamber configured for transfer of the semiconductor substrate between the first reaction chamber and the second reaction chamber without removal from the reactor specifically the reactor housing; wherein the deposition cycles are performed in the first reaction chamber and the etching cycles are performed in the second reaction chamber; and wherein the vapor distribution and removal system is further configured to selectively direct the flow of the metal precursor vapor to at least the first reaction chamber and the flow of the etchant vapor to at least the second reaction chamber.

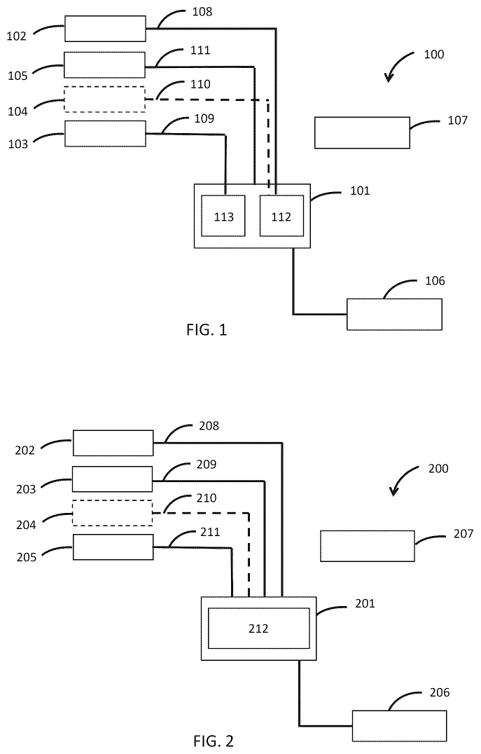

FIG. 1 schematically illustrates an apparatus 100 in accordance with an embodiment of the present disclosure. The apparatus 100 comprises a reactor 101, which includes a first reaction chamber 112 and a second reaction chamber 113. Additionally, the apparatus 100 includes a metal precursor source 102, an etchant source 103, optionally one or more reactant sources 104, a purge gas source 105, an exhaust system 106, and a sequence controller 107. This apparatus is configured to perform the methods disclosed herein and/or fabricate semiconductor devices, such as memory devices, or substructures thereof.

The apparatus 100 may further include a storage device for holding semiconductor substrates. For example, the storage device may be a cassette storage carousel designed to store wafer cassettes, each accommodating multiple semiconductor substrates. The storage device can be operably connected to a substrate handler, such as a robotic arm, configured to transfer individual semiconductor substrates or cassettes between the storage device and the reactor 101.

The reactor 101 may be enclosed within a suitable (reactor) housing that physically contains and isolates the first reaction chamber 112 and the second reaction chamber 113. For the avoidance of doubt, the reactor housing refers specifically to the structural enclosure that forms part of the herein described apparatus 100 and should not be construed as including a cleanroom or other external environmental enclosures in which the apparatus may be situated. This housing configuration forms a closed system or toolset, which advantageously enables both deposition and etching steps to be carried out within the same equipment.

In particular embodiments, the reactor housing is a sealed enclosure specifically designed to contain and isolate the first reaction chamber and the second reaction chamber from the external environment. The reactor housing may be provided with dedicated access ports or windows for maintenance and substrate transfer, which are designed to prevent contamination and leakage during operation. The reactor housing may be provided with ports for the controlled delivery and removal of gases, such as those supplied by the metal precursor source, the etchant source, and any optional reactant sources, as well as for the exhaust system. The housing can be further equipped with integrated seals and barriers to prevent contamination from the external environment, ensuring that the internal process conditions remain unaffected by ambient conditions outside the apparatus.

Unlike a cleanroom, which serves as a general environmental enclosure for housing equipment, the reactor housing is structurally and functionally integrated with the apparatus 100. It does not rely on external environmental controls, such as those provided by cleanroom air filtration systems, to maintain the purity of the reaction environment. Instead, the reactor housing incorporates its own environmental control features, such as temperature regulation, pressure containment, and gas flow management, tailored to the specific requirements of the deposition and etching processes.

The reactor 101 is thus provided with a first reaction chamber 112 and a second reaction chamber 113 for processing semiconductor substrates without removal of the semiconductor substrate from the reactor, specifically the (reactor) housing. Utilizing a single reactor significantly reduces processing time for deposition-etch-deposition processes by eliminating the need to transfer substrates between different reactors or tools, which is introduces significant delays and is operationally less efficient.

The reactor 101 may further comprise components like an insulation material, a heating element, a temperature sensor, a tube, an injector, a flange, a rack and/or a pedestal.

The apparatus 100 can include any number of suitable gas sources 102-105 coupled to the first reaction chamber 112 and/or second reaction chamber 113 within the reactor 101 via lines 108-111, which can include flow controllers, valves, heaters, and the like. The exhaust 106 can include one or more vacuum pumps. The lines 108-111 and exhaust 106 can be used as a distribution and removal system configured to provide vapors of the metal precursor(s), etchant(s), and optionally reactant(s) to the first reaction chamber 112 and/or second reaction chamber 113 within the reactor 101, and to remove the vapors from the first reaction chamber 112 and/or second reaction chamber 113 within the reactor 101.

In a non-limiting exemplary setup, the metal precursor source 102, optionally one or more reactant sources 104, and purge gas source 105 may be connected to the first reaction chamber 112 configured for performing the deposition cycles. In addition, the etchant source 103 and purge gas source 105 may be connected to the second reaction chamber 113 configured for performing the etching cycles.

The metal precursor source 102 can include a vessel and at least one metal precursor as described herein—alone or mixed with one or more carrier (e.g., inert) gases.

The etchant source 103 can include a vessel and at least one etchant as described herein—alone or mixed with one or more carrier (e.g., inert) gases.

The optional one or more reactant sources 104 can include one or more vessels and one or more reactants as described herein—alone or mixed with one or more carrier (e.g., inert) gases. For instance, the apparatus 100 may comprise a first reactant source including a vessel and an oxide reactant; and a second reactant source including a vessel and a nitrogen reactant.

The purge gas source 105 can include one or more inert gases such as N₂ or a noble gas (e.g., argon), as described herein.

The sequence controller 107 may include electronic circuitry and software to selectively operate valves, manifolds, heaters, pumps, and other components included in the apparatus 100. Such circuitry and components operate to introduce precursors, reactants, and purge gases from the respective sources 102-105.

The sequence controller 107 may comprise a memory provided with an executable program which can automate certain tasks such as the flow and timing of gas pulse sequences, temperature of the semiconductor substrate and/or reactor 101, pressure within the reactor 101, and various other operations to provide proper operation of the apparatus 100. The sequence controller 107 can further include control software to electrically or pneumatically control valves to control flow of precursors, etchants, reactants (e.g., oxide reactant, nitrogen reactant, boron reactant, reducing reactant, phosphorous reactant, carbon reactant, or sulfur reactant) and purge gases into and out of the first reaction chamber 112 and/or second reaction chamber 113 within the reactor 101. The sequence controller 107 can include modules such as one or more software and/or hardware component, e.g., a FPGA or ASIC, which perform certain tasks. A module can advantageously be configured to reside on the addressable storage medium of the control system and be configured to execute one or more processes and activate the distribution and removal system during deposition-etch processes.

It should be understood that other configurations of the apparatus 100 are possible, including different numbers and kinds of metal precursors, etchants, reactants, and purge gas sources. Further, it will be appreciated that many arrangements of valves, conduits, metal precursor sources, etchant sources, reactant sources, and purge gas sources may be used to accomplish the goal of selectively feeding vapors into the at least one reaction chamber within the reactor 101. Further, as a schematic representation of an apparatus, many components have been omitted for simplicity of illustration, and such components may include, for example, various valves, manifolds, purifiers, heaters, containers, vents, and/or bypasses.

During operation of the apparatus 100, semiconductor substrates, such as wafers (not illustrated), can be transferred from a storage device to the first reaction chamber 112 and/or second reaction chamber 113 within the reactor 101 by means of a handler. Once the semiconductor substrate(s) are transferred to the at least one reaction chamber, one or more vapors from the respective sources 102-105, such as metal precursors, etchants, reactants, and/or purge gases can be introduced into the first reaction chamber 112 and/or second reaction chamber 113 within the reactor 101 by means of the distribution and removal system (106, and 108-111) operatively connected to the sequence controller 107.

Advantageously, it has been found herein that an apparatus configured as schematically illustrated in FIG. 1, may perform the deposition of a metal-containing film and subsequent etching of this film in the same reactor without the need for additional, specialized equipment. Hence, resulting in a cost-effective technology that may reduce overall processing time.

Alternatively, and in other embodiments, the apparatus may be configured such that the reactor comprises reactor housing enclosing a single reaction chamber; wherein the deposition cycles and etching cycles are performed in the reaction chamber; and wherein the vapor distribution and removal system is further configured to selectively direct and remove the flow of the metal precursor vapor and etchant vapor to the reaction chamber.

Additionally, a skilled person will recognize that the configuration of the apparatus schematically illustrated in FIG. 1 can be readily adapted to include a reactor housing with more than two reaction chambers as described herein, such as three, four, five or more chambers. This expansion remains within the scope of the present disclosure, provided the reactor incorporates a transfer system such as a handling chamber configured for transferring the semiconductor substrate between two or more reaction chambers without removing the semiconductor substrate from the reactor, specifically the reactor housing.

FIG. 2 schematically illustrates an apparatus 200 according to another embodiment of the present disclosure. The apparatus comprises a reactor 201 including a first reactor 201, a metal precursor source 202, an etchant source 203, optionally one or more reactant sources 204, a purge gas source 205, an exhaust 206, and a sequence controller 207. The apparatus 200 can be used to perform methods as disclosed herein and/or form a semiconductor device such as a memory device or substructures thereof.

The reactor 201 may be provided with a suitable (reactor) housing, enclosing the single reaction chamber. This configuration forms a closed system or toolset.

The reactor 201 is thus provided with a single reaction chamber 212 for processing semiconductor substrates without removal of the semiconductor substrate from the reactor, specifically the single reaction chamber. Utilizing a single reactor chamber significantly reduces processing time for deposition-etch-deposition processes by eliminating the need to transfer substrates between different reaction chamber, which introduces significant delays and is operationally less efficient.

The apparatus 200 may further comprise a storage device for storing the semiconductor substrates, such as a cassette storage carousel configured for storing wafer cassettes, each accommodating a plurality of semiconductor substrates. The storage device may be connected to a handler, such as a substrate handling robot configured to transfer individual semiconductor substrates or cassettes between the storage device and the reactor 201.

The reactor 201 may further comprise components like an insulation material, a heating element, a temperature sensor, a tube, an injector, a flange, a rack and/or a pedestal.

The apparatus 200 can include any number of suitable gas sources 202-205 coupled to the reaction chamber 212 within the reactor 201 via lines 208-211, which can include flow controllers, valves, heaters, and the like. The exhaust 206 can include one or more vacuum pumps. The lines 208-211 and exhaust 206 can be used as a distribution and removal system configured to provide vapors of the metal precursor(s), etchant(s), and optionally reactant(s) to the at least one reaction chamber within the reactor 201, and to remove the vapors from the at least one reaction chamber within the reactor 201.

In a non-limiting exemplary setup, the metal precursor source 202, optional one or more reactant sources 204, and purge gas source 205 may be connected to the reaction chamber 212 configured for performing the deposition cycles. In addition, the etchant source 203 and purge gas source 205 may be connected to the reaction chamber 212 configured for performing the etching cycles. Advantageously, this configuration provides that both the deposition and etching step may be performed within the same single reaction chamber without the need for transferring the semiconductor substrate to other reaction chambers or specialized equipment.

The metal precursor source 202 can include a vessel and at least one metal precursor as described herein—alone or mixed with one or more carrier (e.g., inert) gases.

The etchant source 203 can include a vessel and at least one etchant as described herein—alone or mixed with one or more carrier (e.g., inert) gases.

The optional one or more reactant sources 204 can include one or more vessels and one or more reactants as described herein—alone or mixed with one or more carrier (e.g., inert) gases. For instance, the apparatus 200 may comprise a first reactant source including a vessel and an oxide reactant; and a second reactant source including a vessel and a nitrogen reactant.

The purge gas source 205 can include one or more inert gases such as N₂ or a noble gas (e.g., argon), as described herein.

The sequence controller 207 can include electronic circuitry and software to selectively operate valves, manifolds, heaters, pumps and other components included in the apparatus 200. Such circuitry and components operate to introduce precursors, reactants, and purge gases from the respective sources 202-205.

The sequence controller 207 can comprise a memory provided with an executable program which can automate certain tasks such as the flow and timing of gas pulse sequences, temperature of the semiconductor substrate and/or reactor 201, pressure within the reactor 201, and various other operations to provide proper operation of the apparatus 200. The sequence controller 207 can further include control software to electrically or pneumatically control valves to control flow of precursors, etchants, reactants (e.g., oxide reactant, nitrogen reactant, boron reactant, reducing reactant, phosphorous reactant, carbon reactant, or sulfur reactant) and purge gases into and out of the reaction chamber 212 within the reactor 201. The sequence controller 207 can include modules such as one or more software and/or hardware components, e.g., a FPGA or ASIC, which perform certain tasks. A module can advantageously be configured to reside on the addressable storage medium of the control system and be configured to execute one or more processes and activate the distribution and removal system during deposition-etch processes.

It should be understood that other configurations of the apparatus 200 are possible, including different numbers and kinds of metal precursors, etchants, reactants, and purge gas sources. Further, it will be appreciated that many arrangements of valves, conduits, metal precursor sources, etchant sources, reactant sources, and purge gas sources may be used to accomplish the goal of selectively feeding vapors into the at least one reaction chamber within the reactor 201. Further, as a schematic representation of an apparatus, many components have been omitted for simplicity of illustration, and such components may include, for example, various valves, manifolds, purifiers, heaters, containers, vents, and/or bypasses.

During operation of the apparatus 200, semiconductor substrates, such as wafers (not illustrated), can be transferred from a storage device to the reaction chamber 212 within the reactor 201 by means of a handler. Once the semiconductor substrate(s) are transferred to the reaction chamber 212, one or more vapors from the respective sources 202-205, such as metal precursors, etchants, reactants, and/or purge gases can be introduced into the reaction chamber 212 by means of the distribution and removal system 206, and 208-211, operatively connected to the sequence controller 207.

Advantageously, it has been found herein that an apparatus configured as schematically illustrated in FIG. 2, may perform the deposition of a metal-containing film and subsequent etching of this film in the same reaction chamber without the need for additional, specialized equipment. Specifically, the apparatus can perform both (1) cyclic deposition-etch-deposition (dep-etch-dep), where each deposition cycle forms a fraction of the intended film thickness, and (2) deposition of the full intended film thickness followed by etching. The cyclic dep-etch-dep process can be conducted entirely within a single reaction chamber, which enhances throughput by eliminating the need for substrate transfers during processing. Hence, resulting in a cost-effective and versatile technology that may reduce overall processing time while accommodating different manufacturing workflows.

Additionally, a skilled person will recognize that the configuration of the apparatus schematically illustrated in FIG. 2 can be readily adapted to include a reactor housing with more than one reaction chamber, such as two, three, four, or more reaction chambers. This expansion remains within the scope of the present disclosure, provided at least one reaction chamber maintains the configuration of the single reaction chamber in accordance with the embodiment described in reference to FIG. 2. For example, a reactor may comprise two or more reaction chambers as described herein, such as three reaction chambers, four reaction chambers, and so on, each reaction chamber enabling the processing of the semiconductor substrate in said single reaction chamber.

The at least one reactor of the present apparatus may be any suitable system for processing semiconductor substrates, such as ALD reactors as well as CVD reactors equipped with appropriate equipment and means for providing the precursors, reactants, and etchants. According to some embodiments, a showerhead reactor may be used. According to some embodiments, cross-flow, batch, minibatch, or spatial ALD reactors may be used.

In some embodiments, the present apparatus may comprise a vertical furnace as a single reactor. In other embodiments, the present apparatus may comprise a vertical furnace as a first reactor and further comprises a second reactor. In other embodiments, the present apparatus may comprise a vertical furnace as a first reactor and further comprises a vertical furnace as a second reactor.

A vertical furnace operates in a vertical configuration, which optimizes space utilization, enhances uniformity in thermal processing, and allows for precise control of environmental conditions. The at least one reaction chamber (e.g., a vertically oriented cylindrical or tubular structure) of a vertical furnace may advantageously be configured for receiving and processing multiple semiconductor substrates simultaneously. The reaction chamber may be made of a heat-resistant material such as silicon carbide, silicon, or quartz, and is typically enclosed to create a controlled, inert environment for processing reactions. Process gases such as precursor gases, reactant gases, etch gases, cleaning gases, and purge gases, may be provided to the reaction chamber via one or more injector(s).

In some embodiments, the present apparatus may comprise a vertical furnace comprising a first reaction chamber and a second reaction chamber, which may have a vertically oriented cylindrical or tubular structure. In other embodiments, the present apparatus may comprise a vertical furnace comprising a single reaction chamber, which may have a vertically oriented cylindrical or tubular structure.

The vertical furnace may further comprise a carrier constructed and arranged for holding the semiconductor substrates, preferably in a vertically stacked configuration. A suitable carrier includes a boat designed to hold multiple semiconductor substrates vertically in a stacked configuration. The vertical furnace may further be equipped with a boat elevator designed for raising and lowering the boat into and out of the at least one reaction chamber within the vertical furnace. A loading station or substrate handler may be connected to the vertical furnace to load the substrates into the boat prior to insertion into the furnace.

The vertical furnace may further comprise heating elements, typically arranged around the outer circumference of the at least one reaction chamber to provide uniform heat.

In preferred embodiments, the apparatus of the present disclosure may be designed such that one or more of the at least one reactor is a vertical furnace comprising at least one reaction chamber configured to receive and process multiple semiconductor substrates simultaneously.

In particular embodiments, the apparatus of the present disclosure may be designed such that that the at least one reactor further comprises a heating means configured for providing a temperature within the at least one reaction chamber of between 200° C. and 800° C. and/or a pressure regulating mechanism configured for providing a pressure within the reaction chamber between 0.2 Torr and 200 Torr.

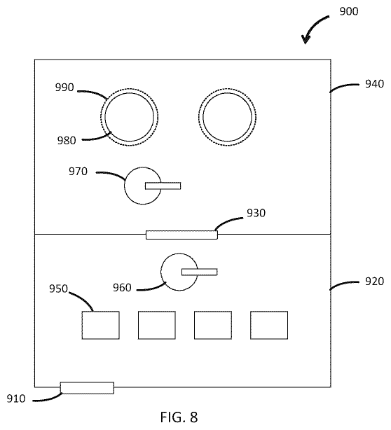

FIG. 8 illustrates a schematic representation of an exemplary vertical furnace system 900, in accordance with an embodiment of the present disclosure. The system is designed for the processing of semiconductor substrates such as semiconductor wafers in a high-temperature reaction chamber through automated handling of said substrates.

The vertical furnace system 900 comprises a cassette transfer port 910, which serves as the entry point for introducing cassettes 950 containing the semiconductor substrates into the system 900. Adjacent to the cassette transfer port 910 is a cassette handling chamber 920, where cassettes storing the semiconductor substrates are temporarily stored and prepared for further handling within the system.

The cassettes 950 can include as FOUPs (Front-Opening Unified Pods) configured for docking at a substrate transfer port 930, enabling secure and controlled access to the substrate for subsequent processing. The substrate handling chamber 940 is located adjacent to the substrate transfer port 930 and provides a clean and isolated environment for substrate transfers.

The cassettes 950 are moved within the cassette handling chamber 920 by a cassette handling robot 960. This robot 960 can include a robotic arm configured to transfer cassettes between the cassette handling chamber 920 and the substrate handling chamber 940.

Within the substrate handling chamber 940, a substrate handling robot 970 facilitates the transfer of individual substrate from the cassettes 950 to a boat 980, which is designed to securely hold substrate in a vertical orientation for processing.

Vertically above the boat 980 is a reaction chamber 990, where high-temperature processes, such as chemical vapor deposition (CVD) or thermal oxidation, are performed. The reaction chamber 990 is thermally insulated and configured to maintain precise environmental conditions necessary for processing semiconductor substrates. The reaction chamber 990 may be configured in accordance with any of the embodiments described herein and may incorporate features as detailed in reference to those embodiments.

In the context of the present disclosure, semiconductor substrate(s) are provided comprising one or more gap features. As used herein, the term “gap feature” may refer to an opening or cavity disposed between two surfaces of a non-planar surface. The term “gap feature” may refer to an opening or cavity disposed between opposing inclined sidewalls of two protrusions extending vertically from the surface of the semiconductor substrate or opposing inclined sidewalls of an indentation extending vertically into the surface of the semiconductor substrate, such a gap feature may be referred to as a “vertical gap feature.” The term “gap feature” may also refer to an opening or cavity disposed between two opposing substantially horizontal surfaces, the horizontal surfaces bounding the horizontal opening or cavity; such a gap feature may be referred to as a “horizontal gap feature.”

In certain embodiments, the one or more gap features are predefined trenches or slots of a memory cell. For instance, in the context of memory devices, the one or more gap features may comprise or form parts of individual wordlines or wordline separators.

In some embodiments, the semiconductor substrate may further comprise metallic materials and surfaces, such as, but not limited to, pure metals, metal nitrides, metal carbides, metal borides, and combinations thereof or mixtures thereof.

The presently described apparatus is configured such that the deposition cycles allow to at least partially fill the one or more gap features with a metal-containing film comprising at least one metal selected from the group consisting of molybdenum (Mo), tungsten (W), ruthenium (Ru), cobalt (Co), nickel (Ni), and mixtures thereof.

In particular embodiments, the metal precursor is a metal halide, metal chalcogenide halide, or metal-organic precursor as defined herein further.

The presently described apparatus is further configured such that the deposited metal-containing film may be subjected to subtractive etching as a result of the etching cycles. The term “subtractive etching” as used herein generally refers to a material removal process used in semiconductor fabrication to (more) precisely define or shape features in a semiconductor substrate or deposited material layer by selectively removing unwanted material. Subtractive etching may be used to form features such as trenches, vias, or isolated components in semiconductor devices or partially fabricated semiconductor devices. For instance, in the context of memory devices, subtractive etching may comprise cutting away parts of the wordline metal fill, thereby separating each wordline from its neighboring wordline.

In particular embodiments, the etchant comprises one or more halogen-containing-etching compounds.

In particular embodiments, the etchant comprises one or more halogen-containing-etching compounds selected from the group consisting of fluorine gas (F₂), chlorine gas (Cl₂), bromine gas (Br₂), quaternary ammonium fluorides, quaternary ammonium chlorides, quaternary ammonium bromides, hydrogen fluoride (HF), hydrogen chloride (HCl), hydrogen bromide (HBr), tetrafluoroboric acid (HBF₄), tetrachloroboric acid (HBCl₄), tetrabromoboric acid (HBBr₄), hexafluorosilicic acid (H₂SiF₆), hexachlorosilicic acid (H₂SiCl₆), hexabromosilicic acid (H₂SiBr₆), tetrabutylammonium tetrafluoroborate, hexafluorozirconic acid (H₂ZrF₆), hexafluorotitanic acid (H₂TiF₆), hexafluorophosphoric acid (HPF₆), molybdenum pentachloride (MoCl₅), tungsten pentachloride (WCl₅), ammonium hexafluorosilicate [(NH₄)₂SiF₆], ammonium hexachlorosilicate [(NH₄)₂SiCl₆], ammonium hexabromosilicate [(NH₄)₂SiBr₆], ammonium hexafluorotitanate [(NH₄)₂TiF₆], ammonium hexachlorotitanate [(NH₄)₂TiCl₆], ammonium hexabromotitanate [(NH₄)₂TiBr₆], thionyl chloride (SOCl₂), and mixtures thereof.

Another aspect of the present disclosure provides a method for at least partially fabricating a semiconductor device or a substructure of the semiconductor device, the method comprising the steps of:
a) providing at least one semiconductor substrate comprising one or more gap features into a reactor comprising at least one reactor chamber;
b) executing one or more deposition cycles within the reactor chamber, each cycle comprising a metal precursor pulse, wherein at least a part of the semiconductor substrate is contacted by at least one metal precursor by introducing the at least one metal precursor into the reactor; wherein the at least one metal precursor comprises at least one metal selected from the group consisting of molybdenum, tungsten, ruthenium, and mixtures thereof; whereby, as a result of the cycles, the metal-containing film is deposited to at least partially fill the one or more gap features of the semiconductor substrate; and;
c) executing one or more etching cycles within the reactor chamber, each cycle comprising an etchant pulse, wherein at least a part of the metal-containing film is contacted by at least one etchant by introducing the at least one etchant into the reactor; whereby, as a result of the cycles, the metal-containing film is subjected to subtractive etching.

It should be clear that (preferred) embodiments and associated advantages of the apparatus according to an aspect of the present disclosure are also (preferred) embodiments of the method for partially fabricating a semiconductor device according to an aspect of the present disclosure and vice versa.

The method(s) disclosed herein generally relate to the formation of features of a semiconductor device with specific electronic properties. In particular, the present method provides for the deposition of a metal-containing film on a semiconductor substrate comprising one or more gap features (e.g., predefined trenches), which in the context of memory devices is also known as a wordline metal fill, followed by a subtractive etch to remove excess metal-containing film and shape the structures into a desired pattern.

In some embodiments, the formed features may serve as individual wordlines or electrical connections for addressing and programming memory cells.

As used herein, the terms “deposition” or “cyclic deposition” or “cyclic deposition process” or “cyclical deposition process” refer to a sequential introduction of precursors (and/or reactants) into a reactor to deposit a layer or film over a semiconductor substrate and includes processing techniques such as atomic layer deposition (ALD), cyclical chemical vapor deposition (cyclical CVD), and hybrid cyclical deposition processes that include an ALD component and a cyclical CVD component. Typically, one deposition cycle may form a metal-containing film or layer of about 0.10 nm. However, the experimental thickness may vary depending on the amount and type of cycles and available reaction sites on the semiconductor substrate.

In some embodiments, the metal-containing film may have a growth rate of about 0.01 nm or less per cycle of precursor(s), optionally reactive gas(es), and purge (e.g., inert carrier) gas(es).

The term “atomic layer deposition” (ALD) refers to a vapor deposition process in which deposition cycles, typically a plurality of consecutive deposition cycles, are conducted in a reactor. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

In preferred embodiments, the present method comprises a cyclic deposition process as part of an atomic layer deposition (ALD) process.

In ALD processes, during each cycle, generally a precursor (e.g., metal precursor) is introduced to a reactor and is chemisorbed to a deposition surface (e.g., a semiconductor substrate surface that can include a previously deposited material from a previous ALD cycle or other material), thereby forming a material, e.g. about a monolayer or sub-monolayer of material, or several monolayers of material, or a plurality of monolayers of material, which does not readily react with additional precursor (i.e., a self-limiting reaction). Thereafter, in some cases, a reactant (e.g., another precursor or reaction gas) may be introduced into the reactor for use in converting the chemisorbed precursor to the desired material on the deposition surface. The reactant can be capable of further reaction with the precursor. It should be noted that, as used herein, ALD processes are not necessarily comprised of a sequence of self-limiting surface reactions.

Optionally, purging steps can be utilized during one or more repetitions, e.g., during each deposition cycle and/or etching cycle, to remove any excess metal precursor from the reactor and/or remove any excess reactant and/or reaction byproducts from the reactor. As used herein, the term “purge” may refer to a procedure in which an inert or substantially inert gas is provided to a reactor in between two pulses of gasses that react with each other. For example, a purge, e.g., using an inert gas such as a noble gas, may be provided between a metal precursor pulse and a reactant pulse, thus avoiding, or at least minimizing gas phase interactions between the metal precursor and the reactant.

Optionally, before deposition the present method may provide a preclean step to remove any impurities from the at least one reaction chamber and/or the to be processed semiconductor substrate.

Advantageously, a cyclical deposition process as disclosed herein can be a thermal deposition process. In other words, in some embodiments, none of the pulses or purges in the cyclical deposition process employs a plasma.

The cyclic deposition step comprising one or more deposition cycles as described herein may include heating the semiconductor substrate to a desired deposition temperature. In some embodiments of the disclosure, the semiconductor substrate may be heated to a temperature of less than approximately 800° C. For example, and in some embodiments, the semiconductor substrate may be heated to a temperature of between approximately 20° C. and less than approximately 800° C., or less than approximately 650° C., or less than approximately 600° C., or between approximately 200° C. and less than approximately 600° C., or between approximately 200° C. and less than approximately 550° C., or between approximately 200° C. and less than approximately 500° C., or between approximately 200° C. and 450° C. In some cases, the temperature of the semiconductor substrate may be approximately the same during the cyclic etching step comprising one or more etching cycles. Alternatively, and in some cases, the temperature of the semiconductor substrate may be lower during the cyclic etching step comprising one or more etching cycles.

In addition to controlling the temperature of the semiconductor substrate, the pressure within the reactor may also be regulated. For example, and in some embodiments, the pressure within the reactor during the one or more deposition cycles may be less than 760 Torr, or between about 0.2 Torr and about 200 Torr, or between about 0.5 Torr and about 50 Torr, or between about 0.5 and about 20 Torr.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process. In such a case, any one of the pulses in the cyclical depositing process may comprise generating a plasma in the reactor.

In some embodiments, the method as disclosed herein may be a continuous vacuum deposition process or continuous vacuum deposition-etch process.

A continuous vacuum deposition process may include depositing a material (e.g., metal-containing film) onto a semiconductor substrate in a reactor without the introduction of atmospheric air or any interruptions that would break the controlled vacuum environment. This process involves maintaining a consistent vacuum pressure within the reactor. In particular embodiments, the method as disclosed herein provides that the metal-containing film is formed without any intervening vacuum break. An advantage of avoiding an intervening vacuum break is that it prevents the need for repeated evacuations and purges that are common in traditional batch deposition methods.

A continuous vacuum deposition-etch process may include depositing a material e.g., metal-containing film) onto a semiconductor substrate in a reactor, and subsequently etching portions of the deposited material without the introduction of atmospheric air or any interruptions that would break the controlled vacuum environment. This process involves maintaining a consistent vacuum pressure within the at least one reaction chamber. An advantage of avoiding an intervening vacuum break during deposition and etching of the metal-containing film is that it prevents the need for repeated evacuations, purges, and/or removal of the semiconductor substrate from the apparatus, which is common in traditional batch approaches.

In particular embodiments, the method as disclosed herein provides that the formation of the metal-containing film may comprise at least 1 deposition cycle, at least 2 deposition cycles, at least 5 deposition cycles, at least 10 deposition cycles, at least 20 deposition cycles, at least 40 deposition cycles, at least 100 deposition cycles, at least 200 deposition cycles, at least 400 deposition cycles, at least 600 deposition cycles, at least 1000 deposition cycles. In some embodiments, the steps may be repeated from at least 1 deposition cycle to at most 1000 deposition cycles, or from at least 2 deposition cycles to at most 100 deposition cycles, or from at least 5 deposition cycles to at most 50 deposition cycles.

A deposition cycle may comprise one or more pulses. In some embodiments, at least one pulse involves a self-limiting surface reaction. In some embodiments, all pulses involve a self-limiting surface reaction. In the context ALD, a self-limiting surface reaction refers to a chemical reaction that automatically halts or slows down once a certain threshold or coverage is reached on a surface, for instance, once a complete monolayer or sub-monolayer is formed the reactions stops by preventing further reaction with additional metal precursor.

In some embodiments, a deposition cycle may comprise one or more metal precursor pulses, and/or optionally one or more reactant pulses.

In some embodiments, a deposition cycle may be followed by an etching cycle, which may be followed by another deposition cycle. Preferably, such deposition-etch-deposition process is performed within the same reaction chamber without any transfer to another reaction chamber. This may advantageously reduce processing time as time-consuming transfers between reaction chambers may be avoided.

In alternative embodiments, a deposition cycle may be performed in a first reaction chamber, while an etching cycle may be performed in a second reaction chamber. The semiconductor substrate is then transferred from the first reaction chamber to the second reaction chamber by a suitable handler (robot). Preferably, the first reaction chamber and the second reaction chamber are enclosed in a single reactor, specifically within the same reactor housing enclosing the first and second reaction chambers.

In some embodiments, the one or more metal precursor pulses last from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

In some embodiments, the one or more optional reactant pulses last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

In some embodiments, the one or more etchant pulses last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

In some cases, the term “precursor” as used herein can refer to a compound that participates in a chemical reaction that produces another compound, particularly a compound that constitutes a film matrix or a main skeleton of a film. The “metal precursor” as described herein may generally refer to a compound that participates in a chemical reaction to produce a metal-containing film as disclosed herein.

In the context of the present disclosure, the at least one metal precursor comprises at least one metal (element) selected from the group consisting of molybdenum (Mo), tungsten (W), ruthenium (Ru), cobalt (Co), nickel (Ni), and mixtures thereof. The metal precursor can include, for example, a molybdenum precursor, a tungsten precursor, a ruthenium precursor, a cobalt precursor, a nickel precursor, or mixtures thereof. Preferably, the at least one metal precursor comprises one or more molybdenum (Mo) precursors for producing a molybdenum-containing film.

It should be understood that the present deposition-etch method is not limited to the production of a single film or layer of one type of material but may include several combinations such as two, three, four, five, six, seven, eight, nine, ten or more metal-containing films.

In a non-limiting exemplary embodiment, a molybdenum-containing film and a tungsten-containing film may be produced. Alternatively, a first molybdenum-containing film and a second molybdenum-containing film may be produced having a different shape and/or thickness.

In another non-limiting exemplary embodiment, a first metal-containing film may be deposited (e.g., a first molybdenum-containing film), followed by a subtractive etch, and subsequently a second metal-containing film may be deposited (e.g., a second molybdenum-containing film), optionally followed by a subtractive etch.

In preferred embodiments, the metal precursor is a metal halide, metal chalcogenide halide, or metal-organic precursor. Suitable metal-organic precursors may comprise cyclopentadienyl, amide, amine, imide, amidinate, alkyl, alkoxide, diketonate, and/or diazabutadiene ligands.

Exemplary molybdenum precursors include a molybdenum halide precursor. The term “molybdenum halide precursor” as used herein may generally refer to a compound which comprises at least a molybdenum component and a halide component, wherein the halide component may include one or more of a chlorine component, a bromine component, or a iodine component. As non-limiting examples, the molybdenum halide precursor may comprise at least one of: molybdenum pentachloride (MoCl₅), molybdenum tetrachloride (MoCl₄), molybdenum hexachloride (MoCl₆), molybdenum trichloride (MoCl₃), molybdenum dichloride (MoCl₂), molybdenum pentabromide (MoBr₅), molybdenum tetrabromide (MoBr₄), molybdenum hexabromide (MoBr₆), molybdenum tribromide (MoBr₃), molybdenum dibromide (MoBr₂), molybdenum pentaiodide (MoI₅), molybdenum tetraiodide (MoI₄), molybdenum hexaiodide (MoI₆), molybdenum triiodide (MoI₃), or molybdenum diiodide (MoI₂). In some embodiments, the molybdenum halide precursor may comprise a molybdenum chalcogenide, and in particular embodiments, the molybdenum halide precursor may comprise a molybdenum chalcogenide halide. For example, the molybdenum chalcogenide halide precursor may comprise a molybdenum oxyhalide selected from the group comprising: a molybdenum oxychloride, a molybdenum oxyiodide, or a molybdenum oxybromide. In particular embodiments of the disclosure, the molybdenum halide precursor may comprise a molybdenum oxychloride, including, but not limited to, molybdenum (V) trichloride oxide (MoOCl₃), molybdenum (VI) tetrachloride oxide (MoOCl₄), or molybdenum (VI) dichloride dioxide (MoO₂Cl₂). Additionally or alternatively, the molybdenum precursor may comprise a metalorganic molybdenum precursor, such as, for example, Mo(CO)₆, Mo(tBuN)₂(NMe₂)₂, Mo(NBu)₂(StBu)₂, (Me₂N)₄Mo, or (iPrCp)₂MoH₂.

Exemplary tungsten precursors include a tungsten halide precursor. The term “tungsten halide precursor” as used herein may generally refer to a compound which comprises at least a tungsten component and a halide component, wherein the halide component may include one or more of a chlorine component, a bromine component, or a iodine component. As non-limiting examples, the tungsten halide precursor may comprise at least one of: tungsten pentachloride (WCl₅), tungsten tetrachloride (WCl₄), tungsten trichloride (WCl₃), tungsten dichloride (WCl₂), tungsten pentabromide (WBr₅), tungsten tetrabromide (WBr₄), tungsten tribromide (WBr₃), tungsten dibromide (WBr₂), tungsten pentaiodide (WI₅), tungsten tetraiodide (WI₄), tungsten triiodide (WI₃), or tungsten diiodide (WI₂). In some embodiments, the tungsten halide precursor may comprise a tungsten chalcogenide, and in particular embodiments, the tungsten halide precursor may comprise a tungsten chalcogenide halide. For example, the tungsten chalcogenide halide precursor may comprise a tungsten oxyhalide selected from the group comprising: a tungsten oxychloride, a tungsten oxyiodide, or a tungsten oxybromide. Additionally or alternatively, the tungsten precursor may comprise cyclopentadienyl compounds of tungsten, tungsten betadiketonate compounds, tungsten alkylamine compounds, tungsten amidinate compounds, or other metalorganic tungsten compounds. In some embodiments, the metalorganic tungsten precursor may comprise bis(tert-butylimino)bis(tertbutylamino)tungsten(VI),bis(isopropylcyclopentadienyl)tungsten(IV)dihyd ride, or tetracarbonyl(1,5-cyclooctadiene)tungsten(0).

Exemplary ruthenium precursors include at least one of: ruthenium tetraoxide (RuO₄), bis(cyclopentadienyl)ruthenium(II), bis(ethylcyclopentadienyl)ruthenium(II), and triruthenium.

Exemplary cobalt precursors include metal-organic cobalt precursors such as cyclopentadienyl compounds of cobalt, cobalt betadiketonate compounds, or cobalt amidinate compounds or other metal-organic cobalt compounds. In some embodiments, the metalorganic cobalt precursor may be selected from the group consisting of bis(acetylacetonate)cobalt(II), bis(ethylcyclopentadienyl)cobalt(II), bis(2,2,6,6-tetramethyl-3,5-heptanedionato)cobalt(II), bis(1,4-di-tert-butyl-1,3-diazabutadiene)cobalt(II), or bis(N-tert-butyl-N′-ethylpropanimidamidato)cobalt(II). Alternatively, a cobalt halide may be used such as cobalt chloride, cobalt bromide, or cobalt iodide.

Exemplary nickel precursors include nickel betadiketonate compounds, nickel betadiketiminato compounds, nickel amidinate compounds, nickel cyclopentadienyl compounds, nickel carbonyl compounds and combinations thereof. The nickel precursor may also comprise one or more halide ligands. In preferred embodiments, the precursor is nickel betadiketiminato compound, such bis(4-N-ethylamino-3-penten-2-N-ethyliminato)nickel (II) [Ni(EtN-EtN-pent)2], nickel ketoiminate, such bis(3Z)-4-nbutylamino-pent-3-en-2-one-nickel(II), nickel amidinate compound, such as methylcyclopentadienyl-isopropylacetamidinate-nickel (II), nickel betadiketonato compound, such as Ni(acac)2, Ni(thd)2 or nickel cyclopentadienyl compounds, such Ni(cp)2, Ni(Mecp)2, Ni(Etcp)2 or derivatives thereof, such as methylcyclopentadienyl-isopropylacetamidinate-nickel (II). In more preferred embodiment, the precursor is bis(4-N-ethylamino-3-penten-2-N-ethyliminato)nickel (II).

At least one of the deposition cycles may further comprise a reactant pulse, wherein at least a part of the semiconductor substrate is contacted by at least one reactant, by introducing the at least one reactant into the reactor. Preferably, the at least one reactant is selected from the group consisting of oxide reactants, nitrogen reactants, boron reactants, reducing reactants, phosphorous reactants, carbon reactants, sulfur reactants, and combinations thereof.

Exemplary oxide reactants include H₂O, O₂, O₃, H₂O₂, N₂O, NO₂, N₂O₄, pyridine N-oxide and O₂ plasma, or mixtures thereof.

Exemplary nitrogen reactants include NH₃, N₂H₄, tert-butyl-hydrazine, 1,1-dimethylhydrazine, methylhydrazine, phenylhydrazine, tert-butylamine, isobutylamine, tert-pentylamine, N₂ plasma, NH₃ plasma and N₂/H₂ plasma, or mixtures thereof.

Exemplary boron reactants include BH₃, B₂H6, B₁₀H₁₄, BF₃, BCl₃, BBr₃, BI₃, B(CH₃)₃, B(CH₂CH₃)₃, B(OCH₃)₃, B[N(CH₃)₂]₃, BH₃[S(CH₃)₂], borazine, trichloroborazine, ammonia-borane, trimethylamine-borane, triethylamine-borane, pyridine-borane, dimethylamine-borane, 2-picoline-borane, tert-butylamine-borane, tetrahydrofuran-borane and pinacolborane, or mixtures thereof.

Exemplary reducing reactants include H₂, H₂ plasma, N₂/H₂ plasma, N₂H₄, tert-butyl hydrazine, 1,1-dimethylhydrazine, formic acid, formalin, pincolborane, B₂H₆, B₁₀H₁₄, BH₃[S(CH₃)₂], ammonia-borane, trimethylamine-borane, triethylamine-borane, pyridine-borane, dimethylamine-borane, 2-picoline-borane, tert-butylamine-borane, tetrahydrofuran-borane, pinacolborane, silane, disilane, trisilane, bis(diethylamino)silane, diisopropylaminosilane and cyclohexadiene, or mixtures thereof.

Exemplary phosphorous reactants include phosphine (PH₃), phosphorus halides, phosphorus oxyhalides, organophosphates, organophosphites, aminophosphines, alkylphosphines, and silylphosphines, or mixtures thereof.

Exemplary carbon reactants include H₂, H₂ plasma, N₂/H₂ plasma, iodomethane, diiodomethane, iodoethane, 1,2-diiodoethane, bromoethane, 1,2-dibromoethane, bromobenzene, iodobenzene, 1-bromobutane, 1-iodobutane, dicyclopentadiene, acetylene, propargyl chloride, propargyl bromide, propargyl iodide, allyl chloride, allyl bromide, allyl iodide and cyclohexadiene, or mixtures thereof.

Exemplary sulfur reactants include H₂S, S₈, S₂Cl₂, tert-butyl thiol, bis(trimethylsilyl)sulfide, 1,2-ethanedithiol, dimethyl disulfide, diethyl disulfide, di-tert-butyl disulfide and carbon disulfide, or mixtures thereof.

The terms “etching” or “cyclical etching” or “cyclic etching process” as used herein refer to a sequential introduction of etchants into a reactor to define or shape features in a semiconductor substrate or deposited material layer by selectively removing unwanted material.

In particular embodiments, the method as disclosed herein provides that the etching of deposited metal-containing film may comprise at least 1 etching cycle, at least 2 etching cycles, at least 5 etching cycles, at least 10 etching cycles, at least 20 etching cycles, at least 40 etching cycles, at least 100 etching cycles, at least 200 etching cycles, at least 400 etching cycles, at least 600 etching cycles, at least 1000 etching cycles. In some embodiments, the steps may be repeated from at least 1 etching cycle to at most 1000 etching cycles, or from at least 2 etching cycles to at most 100 etching cycles, or from at least 5 etching cycles to at most 50 etching cycles. Each etching cycle may comprise one or more etchant pulses.

In some embodiments, the one or more etchant pulses last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

During the etching step of the present method, the same process temperature may be utilized as during the deposition step, or alternatively a different temperature may be used. In some embodiments, the process temperature, i.e., the substrate temperature, during the etch step may be less than approximately 800° C., or less than approximately 700° C., or less than approximately 600° C., or less than approximately 500° C., or less than approximately 400° C., or less than approximately 300° C., or even less than approximately 200° C. In some embodiments of the disclosure, the substrate temperature during the etch stage may be between 200° C. and 800° C., or between 300° C. and 700° C., or between 400° C. and 600° C., or between 525° C. and 575° C.

In addition to achieving a desired process temperature, i.e., a desired substrate temperature, during the (partial) etching of the metal-containing film the reaction chamber pressure may be regulated at the same pressure utilized in the deposition step, or alternatively during the (partial) etching of the metal-containing film the reaction chamber pressure may be different to that utilized in the deposition step. In some embodiments, the reaction chamber pressure may be regulated to be less than 760 Torr, or between about 0.2 Torr and about 200 Torr, or between about 0.5 Torr and about 50 Torr, or between about 0.5 and about 20 Torr.

In some embodiments, the etch rate of the metal-containing film may be less than 10 Angstroms per second, or less than 8 Angstroms per second, or less than 6 Angstroms per second, or less than 4 Angstroms per second, or even less than 2 Angstroms per second. For example, the (partial) etching of the metal-containing film may comprise etching a thickness of the metal-containing film of less than 20 Angstroms, or less than 10 Angstroms, or even less than 5 Angstroms. In some embodiments, the etchant may preferentially etch the metal-containing film in proximity to the entrance of one or more gap features, thereby maintaining an opening to the one or more gap features for subsequent metal gap fill processes.

Next to an etchant pulse, each cycle may further comprise purging the reaction chamber. For example, etchant gas and reaction byproducts (if any) may be removed from the surface of the semiconductor substrate, e.g., by pumping with an inert gas. In some embodiments of the disclosure, the purge process may comprise a purge cycle wherein the semiconductor substrate surface is purged for a time period of less than approximately 10.0 seconds, or less than approximately 5.0 seconds, or even less than approximately 2.0 seconds. Excess etchant gas and any possible reaction byproducts may be removed with the aid of a vacuum, generated by a pumping system in fluid communication with the reaction chamber.

The term “etchant” as used herein can refer to a chemical substance or reactive medium used in semiconductor fabrication to selectively remove material from a substrate or thin film layer during an etching process. Suitable etchants in the present context include halogen-containing compounds.

In particular embodiments, the etchant comprises one or more halogen-containing-etching compounds selected from the group consisting of fluorine gas (F₂), chlorine gas (Cl₂), bromine gas (Br₂), quaternary ammonium fluorides, quaternary ammonium chlorides, quaternary ammonium bromides, hydrogen fluoride (HF), hydrogen chloride (HCl), hydrogen bromide (HBr), tetrafluoroboric acid (HBF₄), tetrachloroboric acid (HBCl₄), tetrabromoboric acid (HBBr₄), hexafluorosilicic acid (H₂SiF₆), hexachlorosilicic acid (H₂SiCl₆), hexabromosilicic acid (H₂SiBr₆), tetrabutylammonium tetrafluoroborate, hexafluorozirconic acid (H₂ZrF₆), hexafluorotitanic acid (H₂TiF₆), hexafluorophosphoric acid (HPF₆), molybdenum pentachloride (MoCl₅), tungsten pentachloride (WCl₅), ammonium hexafluorosilicate [(NH₄)₂SiF₆], ammonium hexachlorosilicate [(NH₄)₂SiCl₆], ammonium hexabromosilicate [(NH₄)₂SiBr₆], ammonium hexafluorotitanate [(NH₄)₂TiF₆], ammonium hexachlorotitanate [(NH₄)₂TiCl₆], ammonium hexabromotitanate [(NH₄)₂TiBr₆], thionyl chloride (SOCl₂), and mixtures thereof.

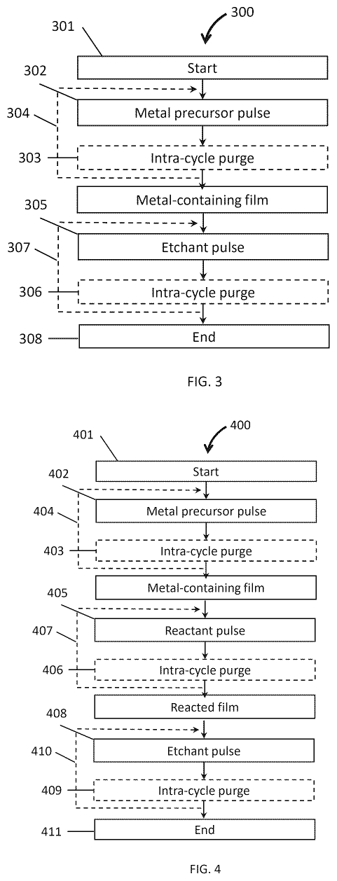

FIG. 3 describes a method 300 according to an embodiment of the present disclosure for partially fabricating a semiconductor device or a substructure of the semiconductor device.

The method begins 301 when a semiconductor substrate comprising one or more gap features is provided to a reaction chamber constructed and arranged within a reactor. The semiconductor substrate may be any substrate as defined herein. The reactor can be a standalone reactor or part of a cluster tool.

The cyclical deposition comprises contacting one or more metal precursor(s) with at least a part of the semiconductor substrate in a metal precursor pulse 302. Optionally, the reaction chamber can be purged 303 after the metal precursor pulse 302. The metal precursor pulse 302 and the optional purge 303 can be repeated 304 any number of times to obtain a metal-containing film of a desired thickness.

Next, the method 300 continues by contacting one or more etchant(s) with at least a part of the formed metal-containing film in an etchant pulse 305. Optionally, the reaction chamber can be purged 306 after the etchant pulse 305. The etchant pulse 305, and optional purge 306 can be repeated 307 any number of times.

The method 300 concludes 308 when a feature of the semiconductor device of a desired shape and thickness is formed based on any combination of the aforementioned steps. Once the method has ended, the semiconductor substrate can be subjected to additional processes known in the art for forming a semiconductor device, such as a memory device structure and/or memory device.

FIG. 4 describes a method 400 according to another embodiment of the present disclosure for partially fabricating a semiconductor device or a substructure of the semiconductor device.

The method starts 401 after a semiconductor substrate comprising one or more gap features has been provided to a reaction chamber constructed and arranged within a reactor. The semiconductor substrate may be any substrate as defined herein. The reactor can be a standalone reactor or part of a cluster tool.

The cyclical deposition comprises contacting one or more metal precursor(s) with at least a part of the semiconductor substrate in a metal precursor pulse 402. Optionally, the reaction chamber is purged 403 after the metal precursor pulse 402. The metal precursor pulse 402, and optional purge 403 can be repeated 404 any number of times to obtain a metal-containing film of a desired thickness.

Next, the cyclical deposition process continues by contacting one or more reactants with at least a part of the semiconductor substrate and/or deposited metal-containing film in a reactant pulse 405. Optionally, the reaction chamber can be purged 406 after the reactant pulse 405. The reactant pulse 405, and optional purge 406 can be repeated 407 any number of times.

Next, the method 400 continues by contacting one or more etchant(s) with at least a part of the formed metal-containing film in an etchant pulse 408. Optionally, the reaction chamber can be purged 409 after the etchant pulse 408. The etchant pulse 408, and optional purge 409 can be repeated 410 any number of times.

The method 400 concludes 411 when a feature of the semiconductor device of a desired shape and thickness is formed based on any combination of the aforementioned steps. Once the method has ended, the semiconductor substrate can be subjected to additional processes known in the art for forming a semiconductor device, such as a memory device structure and/or memory device.

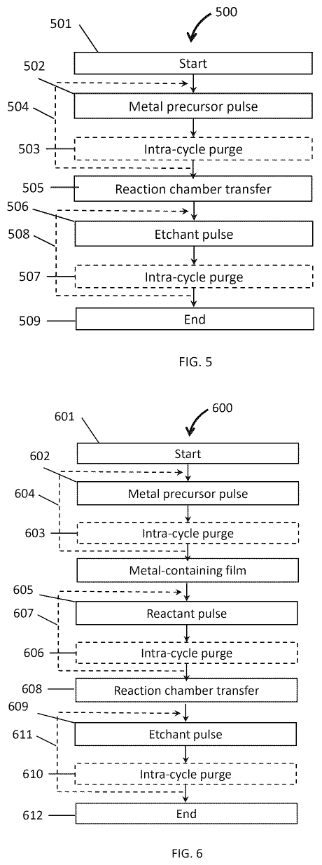

FIG. 5 describes a method 500 according to yet another embodiment of the present disclosure for partially fabricating a semiconductor device or a substructure of the semiconductor device.

The method starts 501 after a semiconductor substrate comprising one or more gap features has been provided to a first reaction chamber constructed and arranged within a reactor. The semiconductor substrate may be any substrate as defined herein. The reactor can be a standalone reactor or part of a cluster tool.

The cyclical deposition comprises contacting one or more metal precursor(s) with at least a part of the semiconductor substrate in a metal precursor pulse 502. Optionally, the first reaction chamber is purged 503 after the metal precursor pulse 502. The metal precursor pulse 502, and optional purge 503 can be repeated 504 any number of times to obtain a metal-containing film of a desired thickness.

After deposition of the metal-containing film, the semiconductor substrate is transferred 505 from the first reaction chamber to a second reaction chamber constructed and arranged within the reactor. Next, the process continues by contacting one or more etchant(s) with at least a part of the formed metal-containing film in an etchant pulse 506. Optionally, the second reaction chamber can be purged 507 after the etchant pulse 506. The etchant pulse 506, and optional purge 507 can be repeated 508 any number of times.

The method 500 concludes 509 when a feature of the semiconductor device of a desired shape and thickness is formed based on any combination of the aforementioned steps. Once the method has ended, the semiconductor substrate can be subjected to additional processes known in the art for forming a semiconductor device, such as a memory device structure and/or memory device.

FIG. 6 describes a method 600 according to yet another embodiment of the present disclosure for partially fabricating a semiconductor device or a substructure of the semiconductor device.

The method 600 starts 601 after a semiconductor substrate comprising one or more gap features has been provided to a first reaction chamber constructed and arranged within a reactor. The semiconductor substrate may be any substrate as defined herein. The reactor can be a standalone reactor or part of a cluster tool.

The cyclical deposition comprises contacting one or more metal precursor(s) with at least a part of the semiconductor substrate in a metal precursor pulse 602. Optionally, the first reaction chamber is purged 603 after the metal precursor pulse 602. The metal precursor pulse 602, and optional purge 603 can be repeated 604 any number of times to obtain a metal-containing film of a desired thickness.

Next, the cyclical deposition process continues by contacting one or more reactants with at least a part of the semiconductor substrate and/or deposited metal-containing film in a reactant pulse 605. Optionally, the first reaction chamber can be purged 606 after the reactant pulse 605. The reactant pulse 605, and optional purge 606 can be repeated 607 any number of times.

After contacting the metal-containing film with the one or more reactants, the semiconductor substrate is transferred 608 from the first reaction chamber to a second reaction chamber constructed and arranged within the reactor. Next, the process continues by contacting one or more etchant(s) with at least a part of the formed metal-containing film in an etchant pulse 609. Optionally, the second reaction chamber can be purged 610 after the etchant pulse. The etchant pulse 609, and optional purge 610 can be repeated 611 any number of times.

The method 600 concludes 612 when the individual wordlines of a desired shape and thickness are formed based on any combination of the aforementioned steps. Once the method has ended, the semiconductor substrate can be subjected to additional processes known in the art for forming a semiconductor device, such as a memory device structure and/or memory device.

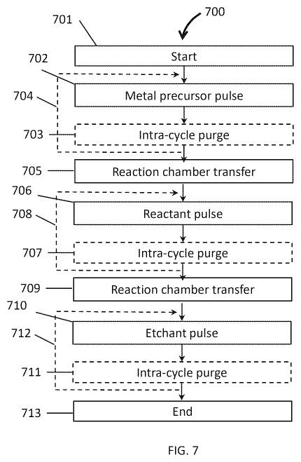

FIG. 7 describes a method 700 according to yet another embodiment of the present disclosure for partially fabricating a semiconductor device or a substructure of the semiconductor device.

The method 700 starts 701 after a semiconductor substrate comprising one or more gap features has been provided to a first reaction chamber constructed and arranged within a reactor. The semiconductor substrate may be any substrate as defined herein. The reactor can be a standalone reactor or part of a cluster tool.

The cyclical deposition comprises contacting one or more metal precursor(s) with at least a part of the semiconductor substrate in a metal precursor pulse 702. Optionally, the first reaction chamber is purged 703 after the metal precursor pulse 702. The metal precursor pulse 702, and optional purge 703 can be repeated 704 any number of times to obtain a metal-containing film of a desired thickness.

After deposition of the metal-containing film, the semiconductor substrate is transferred 705 from the first reaction chamber to a second reaction chamber constructed and arranged within the reactor. Next, the cyclical deposition process continues by contacting one or more reactants with at least a part of the semiconductor substrate and/or deposited metal-containing film in a reactant pulse 706. Optionally, the first reaction chamber can be purged 707 after the reactant pulse 706. The reactant pulse 706, and optional purge 707 can be repeated 708 any number of times.

After contacting the metal-containing film with the one or more reactants, the semiconductor substrate is transferred 709 from the second reaction chamber to a third reaction chamber constructed and arranged within the reactor. Next, the process continues by contacting one or more etchant(s) with at least a part of the formed metal-containing film in an etchant pulse 710. Optionally, the second reaction chamber can be purged 711 after the etchant pulse. The etchant pulse 710, and optional purge 711 can be repeated 712 any number of times.

The method 700 concludes 713 when the individual wordlines of a desired shape and thickness are formed based on any combination of the aforementioned steps. Once the method has ended, the semiconductor substrate can be subjected to additional processes known in the art for forming a semiconductor device, such as a memory device structure and/or memory device.

Another aspect of the present disclosure provides a semiconductor device comprising one or more gap features filled with a metal-containing film prepared with the device according to an aspect of the present disclosure or (preferred) embodiments thereof or by means of the method according to an aspect of the present disclosure or (preferred) embodiments thereof.

It should be clear that (preferred) embodiments and associated advantages of the apparatus and method according to an aspect of the present disclosure are also (preferred) embodiments of the semiconductor device according to an aspect of the present disclosure and vice versa.

In particular embodiments, the present semiconductor device is a memory device. The term “memory device,” as used herein, refers to an electronic component designed to store, retain, and retrieve digital information. It may employ various physical mechanisms known in the art to represent and store data in a manner that allows for subsequent access and manipulation. Memory devices are integral components of computing systems and electronic devices, facilitating tasks such as data storage, retrieval, processing, and transfer. In the context of memory devices, MIM capacitors are important components for data storage and retrieval. The method disclosed herein is particularly suitable for producing MIM capacitors having a high charge retention and fast charge release, thus resulting in memory devices with more reliable data storage and retrieval. Non-limiting exemplary memory devices include at least one of a 3D-NAND device, a DRAM device, a 3D-integrated device, or an integrated logic device, or a partially fabricated memory device structure including at least one of a 3D-NAND device structure, a DRAM device structure, a 3D-integrated device structure, or a partially fabricated integrated logic device structure.

In embodiments wherein the semiconductor device comprises a (partially) fabricated DRAM device structure, the semiconductor substrate may comprise a plurality of features comprising a plurality of DRAM wordlines.

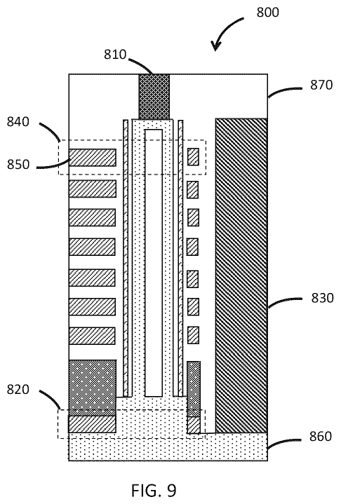

FIG. 9 illustrates a schematic cross-sectional view of an exemplary semiconductor memory device 800 in accordance with an embodiment of the present disclosure. Specifically, this figure depicts a channel cross-section of a 3D NAND device 800. The device 800 comprises a bit line 810, which can be used to read and write data to the memory device by connecting to the drains or sources of multiple transistors within a memory array (not shown).

The bit line 810 is positioned at the top of the memory string, opposite to the bottom select gate 820 that is located at the base of the vertical memory string. The bottom select gate 820 controls the connection between the memory string and the source line, enabling or disabling the flow of current during memory operations such as read, write, or erase. The bottom select gate 820 is positioned adjacent to the conductive channel 860, which acts as the conduction path for carriers between the source and drain terminals.

Arranged between the bit line 810 and the bottom select gate 820 is a plurality of floating-gate transistors 840 configured to store electric charges, which represent the binary data of the memory device. Each floating-gate transistor 840 is associated with a specific wordline 850 as described herein. The floating-gate transistors 840 are vertically supported by spacer 870 that defines the dimensions of wordlines and channel openings. The spacer 870 may include a dielectric material.

The wordlines 850 serve as the control gate for the floating-gate transistor and can be used to address and operate the transistor 840 during memory operations. Each layer in the vertical stack includes a wordline that controls the floating-gate transistor at that level. For example, in a memory string with 64 layers, there would be 64 wordlines controlling 64 floating-gate transistors in that string. The shared channel in the vertical stack connects to the drain 830 enabling the flow of current that is necessary for the memory operations.

1. An apparatus, comprising
at least one reactor comprising at least one reaction chamber constructed and arranged for processing at least one semiconductor substrate; wherein the semiconductor substrate comprises one or more gap features;
a metal precursor source constructed and arranged to provide a vapor of at least one metal precursor comprising at least one metal selected from the group consisting of molybdenum, tungsten, ruthenium, cobalt, nickel, and mixtures thereof;
an etchant source constructed and arranged to provide a vapor of at least one etchant;
a vapor distribution and removal system configured to provide the vapors of the metal precursor source and the etchant source to the at least one reaction chamber within the reactor, and to remove the vapors from the reaction chamber; and
a sequence controller operably connected to the distribution and removal system, comprising a memory provided with a program configured to control the flow from the metal precursor source to the reactor chamber by activating the vapor distribution and removal system during one or more deposition cycles; whereby, as a result of the deposition cycles, a metal-containing film is deposited to at least partially fill the one or more gap features of the semiconductor substrate; and, wherein the program is further configured to control the flow from the etchant source to the reactor chamber by activating the vapor distribution and removal system during one or more etching cycles; whereby, as a result of the etching cycles, the metal-containing film is subjected to subtractive etching.

2. The apparatus according to claim 1, further comprising a reactant source constructed and arranged to provide a vapor of a reactant; wherein the vapor distribution and removal system is further configured to provide the vapor of the reactant source to the reactor; and wherein the program provided on the memory is configured to control the flow of the reactant from the reactant source to the at least one reactor chamber during the one or more deposition cycles.

3. The apparatus according to claim 1, wherein the reactant is selected from the group consisting of oxide reactant, nitrogen reactant, boron reactant, reducing reactant, phosphorous reactant, carbon reactant, sulfur reactant, and combinations thereof.

4. The apparatus according to claim 1, wherein the program provided on the memory is further configured to control the flow from the metal precursor source to the at least one reactor chamber by activating the vapor distribution and removal system during the one or more deposition cycles comprised in a cyclic deposition process as part of an atomic layer deposition process.

5. The apparatus according to claim 1, wherein the at least one semiconductor substrate further comprises a material selected from the group consisting of silicon, silicon oxide, silicon germanium, carbon doped silicon oxides, silicon nitride, silicon carbide, germanium, gallium arsenide, gallium nitride, glass, sapphire, and combinations thereof.

6. The apparatus according to claim 1, wherein the metal precursor is a metal halide, metal chalcogenide halide, or metal-organic precursor.

7. The apparatus according to claim 1, wherein the etchant comprises one or more halogen-containing-etching compounds.

8. The apparatus according to claim 1, wherein the etchant comprises one or more halogen-containing-etching compounds selected from the group consisting of F₂, Cl₂, Br₂, quaternary ammonium fluorides, quaternary ammonium chlorides, quaternary ammonium bromides, HF, HCl, HBr, tetrafluoroboric acid, tetrachloroboric acid, tetrabromoboric acid, hexafluorosilicic acid, hexachlorosilicic acid, hexabromosilicic acid, tetrabutylammonium tetrafluoroborate, H₂ZrF₆, H₂TiF₆, HPF₆, MoCl₅, WCl₅, ammonium hexafluorosilicate, ammonium hexachlorosilicate, ammonium hexabromosilicate, ammonium hexafluorotitanate, ammonium hexachlorotitanate, ammonium hexabromotitanate, thionyl chloride, and mixtures thereof.

9. The apparatus according to claim 1, wherein the at least one reactor further comprises a heating means configured for providing a temperature within the reactor chamber of between 200° C. and 800° C.

10. The apparatus according to claim 1, wherein the at least one reactor further comprises a pressure regulating mechanism configured for providing a pressure within the reactor chamber between 0.2 Torr and 200 Torr.

11. The apparatus according to claim 1, wherein one or more of the at least one reactor is a vertical furnace comprising at least one reaction chamber configured to receive and process multiple semiconductor substrates simultaneously.

12. The apparatus according to claim 1, wherein the reactor comprises a reactor housing enclosing at least a first reaction chamber and a second reaction chamber, and a handling chamber configured for transfer of the semiconductor substrate between the first and second reaction chambers; wherein the one or more deposition cycles are performed in the first reaction chamber and the one or more etching cycles are performed in the second reaction chamber; and wherein the vapor distribution and removal system is further configured to selectively direct the flow of the metal precursor vapor to at least the first reaction chamber and the flow of the etchant vapor to at least the second reaction chamber.

13. The apparatus according to claim 1, wherein the reactor comprises a reactor housing enclosing a single reaction chamber; wherein the one or more deposition cycles and the one or more etching cycles are performed within the reaction chamber; and wherein the vapor distribution and removal system is further configured to selectively direct and remove the flow of the metal precursor vapor and etchant vapor to the reaction chamber.

14. A method for at least partially fabricating a semiconductor device, the method comprising the steps of:
a) providing at least one semiconductor substrate comprising one or more gap features into a reactor comprising at least one reactor chamber;
b) executing one or more deposition cycles within the reactor chamber, each cycle comprising
a metal precursor pulse, wherein at least a part of the semiconductor substrate is contacted by at least one metal precursor by introducing the at least one metal precursor into the reactor; wherein the at least one metal precursor comprises at least one metal selected from the group consisting of molybdenum, tungsten, ruthenium, and mixtures thereof;
whereby, as a result of the cycles, the metal-containing film is deposited to at least partially fill the one or more gap features of the semiconductor substrate; and,
c) executing one or more etching cycles within the reactor chamber, each cycle comprising
an etchant pulse, wherein at least a part of the metal-containing film is contacted by at least one etchant by introducing the at least one etchant into the reactor;
whereby, as a result of the cycles, at least part of the metal-containing film is subjected to subtractive etching.

15. The method according to claim 14, wherein the at least one deposition cycle further comprises a reactant pulse, wherein at least a part of the semiconductor substrate is contacted by at least one reactant, by introducing the at least one reactant into the reactor;

16. The method according to claim 15, wherein the at least one reactant is selected from the group consisting of oxide reactant, nitrogen reactant, boron reactant, reducing reactant, phosphorous reactant, carbon reactant, sulfur reactant, and combinations thereof.

17. The method according to claim 14, wherein the reactor comprises a reactor housing enclosing at least a first reaction chamber and a second reaction chamber and a handling chamber configured for transfer of the semiconductor substrate between the first and second reaction chambers; and wherein the one or more deposition cycles are performed in the first reaction chamber and the etching cycles are performed in the second reaction chamber without removal of the semiconductor substrate from the reactor.

18. The method according to claim 14, wherein the reactor comprises a reactor housing enclosing a single reaction chamber; and wherein the one or more deposition cycles and the one or more etching cycles are performed within the reaction chamber without removal of the semiconductor substrate from the reactor.

19. A semiconductor device comprising one or more gap features filled with a metal-containing film prepared by means of the method according to claim 14.

20. The semiconductor device according to claim 19, wherein the semiconductor device is a memory device including at least one of a 3D-NAND device, a DRAM device, a 3D-integrated device, or an integrated logic device, or
a partially fabricated memory device structure including at least one of a 3D-NAND device structure, a DRAM device structure, a 3D-integrated device structure, or a partially fabricated integrated logic device structure.
